(19) United States
(12) Patent Application Publication
(10) Pub. No.: US 2026/0271391 A1
(43) Pub. Date: Sep. 10, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Guan-Lin CHEN, Hsinchu (TW); Wei-Hsuan LIN, Hsinchu (TW); Chung-En TSAI, Hsinchu (TW); Cheng-Han LEE, Hsinchu (TW); Ming-Han LIAO, Hsinchu (TW); Kuo-Cheng CHIANG, Hsinchu (TW)

(73) Assignee: Taiwan Semiconductor Manufacturing Company, Ltd., Hsinchu (TW)

(21) Appl. No.: 19/074,092

(22) Filed: Mar. 7, 2025

(51) Int. Cl. H10D 84/85; H10D 30/00; H10D 30/01; H10D 30/43; H10D 30/47; H10D 62/10; H10D 62/832; H10D 62/834; H10D 84/01

(52) U.S. Cl. CPC H10D 84/851; H10D 30/014; H10D 30/0194; H10D 30/43; H10D 30/47; H10D 30/504; H10D 62/102; H10D 62/121; H10D 62/832; H10D 62/834; H10D 84/0167

(57) ABSTRACT

A method of manufacturing a semiconductor device is provided. A stack of nanostructures having a plurality of first semiconductor layers, a plurality of diffusion barrier layers and a plurality of second semiconductor layers alternately stacked is formed, wherein each of the diffusion barrier layers is disposed between the first and second semiconductor layers. Edge portions of the second semiconductor layers is removed to form a plurality of cavities between the diffusion barrier layers. A dielectric spacer is formed on sidewalls of the second semiconductor layers and fills the cavities. An epitaxial source/drain feature is formed such that a side surface of the epitaxial source/drain feature contacts the first semiconductor layers, the diffusion barrier layers and the dielectric spacers.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

Recently, multi-gate devices have been introduced into fin field-effect transistors (FinFETs). FinFETs have been used in various applications, for example, to implement logic devices/circuits or the like. Generally speaking, logic devices may focus on electrical performance (e.g., threshold voltage, saturation current, and breakdown voltage etc.). However, optimization of the performance and/or design requirements of FinFET devices has been challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device in accordance with some embodiments.

FIGS. 7A and 7B are cross-sectional views of the semiconductor device taken along line A-A and line B-B of FIG. 6, respectively.

FIGS. 8A-8B are cross-sectional views of the semiconductor device taken along line A-A of FIG. 6, showing various stages of manufacturing the semiconductor device in accordance with some embodiments.

FIGS. 9A-14A are cross-sectional views of various stages of manufacturing the semiconductor device taken along cross-section A-A of FIG. 6, in accordance with some embodiments.

FIGS. 9B-14B are cross-sectional views of various stages of manufacturing the semiconductor device taken along cross-section B-B of FIG. 6, in accordance with some embodiments.

FIG. 15 illustrates a comparison of germanium gradient and carbon concentration in three nanostructures containing SiGe/Si, SiGe/SiGeC/Si and SiGe/SiGeC/Si.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs (e.g. Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure.

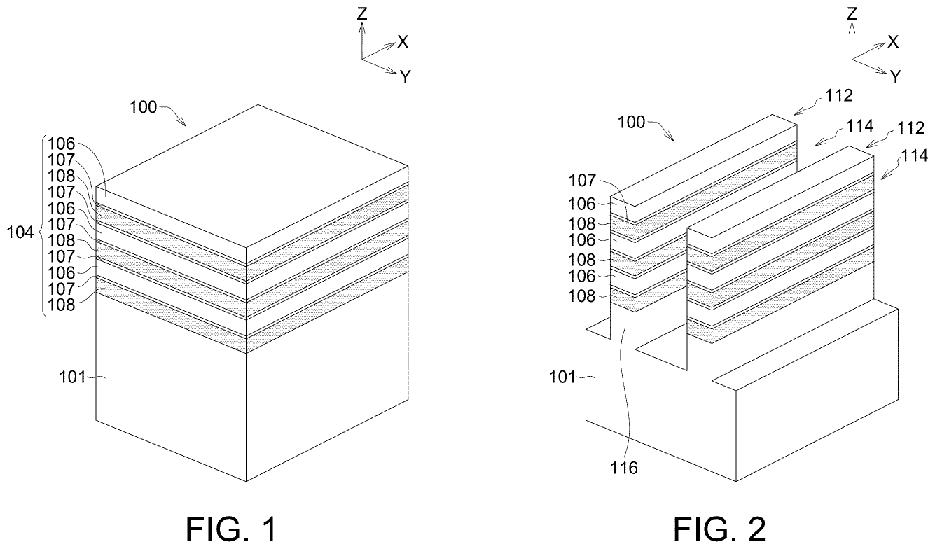

FIGS. 1-14B show exemplary processes for manufacturing a semiconductor device 100 according to embodiments of the present disclosure. It is understood that additional operations can be provided before, during, and after processes shown by FIGS. 1-14B, and some of the operations described below can be replaced or eliminated, for additional embodiments of the method. The order of the operations/processes is not limiting and may be interchangeable.

FIGS. 1-6 are perspective views of various stages of manufacturing a semiconductor device 100 in accordance with some embodiments. As shown in FIG. 1, a semiconductor device 100 includes a stack of semiconductor layers 104 formed over a substrate 101. The substrate 101 may be a semiconductor substrate. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example boron for p-type field effect transistors (PFET) and phosphorus for n-type field effect transistors (NFET).

The stack of semiconductor layers 104 includes semiconductor layers made of different materials to facilitate formation of nanostructure channels in a multi-gate device, such as nanostructure FETs. In some embodiments, the stack of semiconductor layers 104 includes first semiconductor layers 106, diffusion barrier layers 107 and second semiconductor layers 108. In some embodiments, the stack of semiconductor layers 104 includes alternating first and second semiconductor layers 106, 108, and the first and second semiconductor layers 106, 108 are disposed in parallel with each other. Each of the diffusion barrier layers 107 are disposed between alternating first and second semiconductor layers 106 and 108. The first semiconductor layers 106 and the second semiconductor layers 108 are made of semiconductor materials having different etch selectivity and/or oxidation rates. The diffusion barrier layers 107 are made of semiconductor materials having elements, such as carbon (C), tellurium (Te), antimony (Sb), tin (Sn) or a combination thereof. For example, the first semiconductor layers 106 may be made of Si and the second semiconductor layers 108 may be made of SiGe. In some examples, the first semiconductor layers 106 may be made of Si doped with Ge and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof. The diffusion barrier layers 107 may be made of SiGeM having a M concentration range between 0.1% and 10%, wherein M may be at least one element selected from carbon (C), tellurium (Te), antimony (Sb), tin (Sn) or a combination thereof. For example, the diffusion barrier layers 107 may be made of SiGeC having a carbon concentration range between 0.1% and 10%.

The thickness of the first semiconductor layers 106 and the second semiconductor layers 108 may vary depending on the application and/or device performance considerations. In some embodiments, each first and second semiconductor layer 106, 108 has a thickness in a range between about 2 nm and about 30 nm. In other embodiments, each first and second semiconductor layer 106, 108 has a thickness in a range between about 3 nm and about 20 nm. In some embodiments, each first and second semiconductor layer 106, 108 has a thickness in a range between about 6 nm and about 12 nm. Each second semiconductor layer 108 may have a thickness that is equal to, less than, or greater than the thickness of the first semiconductor layer 106. The second semiconductor layers 108 may eventually be removed and serve to define a vertical distance between adjacent channels for the semiconductor device 100. The diffusion barrier layers 107 may have a thickness in a range between about 0.3 nm and about 5 nm. In some embodiments, when the diffusion barrier layers 107 made of SiGeC having a carbon concentration of 0.1%, the diffusion barrier layers 107 made of SiGeC may have a thickness of about 5 nm. In other embodiments, when the diffusion barrier layers 107 made of SiGeC having a carbon concentration of 2%, the diffusion barrier layers 107 made of SiGeC may have a thickness of about 0.3 nm.

The first semiconductor layers 106 or portions thereof may form nanostructure channel(s) of the semiconductor device 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device 100 may be surrounded by a gate electrode. The semiconductor device 100 may include a nanostructure transistor. The nanostructure transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device 100 is further discussed below. The use of the diffusion barrier layers 107 is to retard SiGe intermix between the first semiconductor layers 106 and the second semiconductor layers 108. Less SiGe intermix is formed and better surface roughness of the nanostructure channels can be achieved by the insertion of diffusion barrier layers 107 when the second semiconductor layers 108 are removed.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. The diffusion barrier layers 107 are formed by any suitable deposition process, such as CVD or atomic layer deposition (ALD) process, or any suitable surface treatment of C/Tb/Sb/Sn insertion on semiconductor layers to reduce SiGe intermix. While three first semiconductor layers 106, three second semiconductor layers 108 and five diffusion barrier layers 107 are alternately arranged as illustrated in FIG. 1, it can be appreciated that any number of first and second semiconductor layers 106, 108 and the diffusion barrier layers 107 can be formed in the stack of semiconductor layers 104, depending on the predetermined number of nanostructure channels for each FET. For example, the number of first semiconductor layers 106, which is the number of channels, may be between 2 and 8.

In some embodiments, carbon is chosen for its small atomic radius, which is almost twice smaller than that of Ge. Carbon atoms are thus highly mobile and can easily fulfill both vacancies and interstitial sites of the lattice of the first and second semiconductor layers 106 and 108. This indicates that carbon adsorption on the surface of the first and second semiconductor layers 106 and 108 with a well-controlled amount and does not affect the epitaxial growth of first and second semiconductor layers 106 and 108. In an example for silicon based nanostructure semiconductor device, dummy SiGe layer removal for Si nanostructure semiconductor device results in serious surface roughness to degrade the carrier mobility and influences the capability for further sheet height scaling. Insertion of SiGeC layers (i.e. diffusion barrier layers 107) between dummy SiGe layers and Si-channel layers or the additional carbon treatment on the Si-channel layers can reduce SiGe intermix and improve the surface roughness of the Si-channel layers to scale the nanostructures height for better device performance. In one embodiment, with the insertion of SiGeC layers (i.e. diffusion barrier layers 107), the surface roughnesses of the first semiconductor layers 106 may be in the range between about 0.13 nm and about 0.16 nm.

In FIG. 2, fin structures 112 are formed from the stack of semiconductor layers 104. Each of the fin structures 112 has an upper portion including the semiconductor layers 106, 108 and the diffusion barrier layers 107, and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

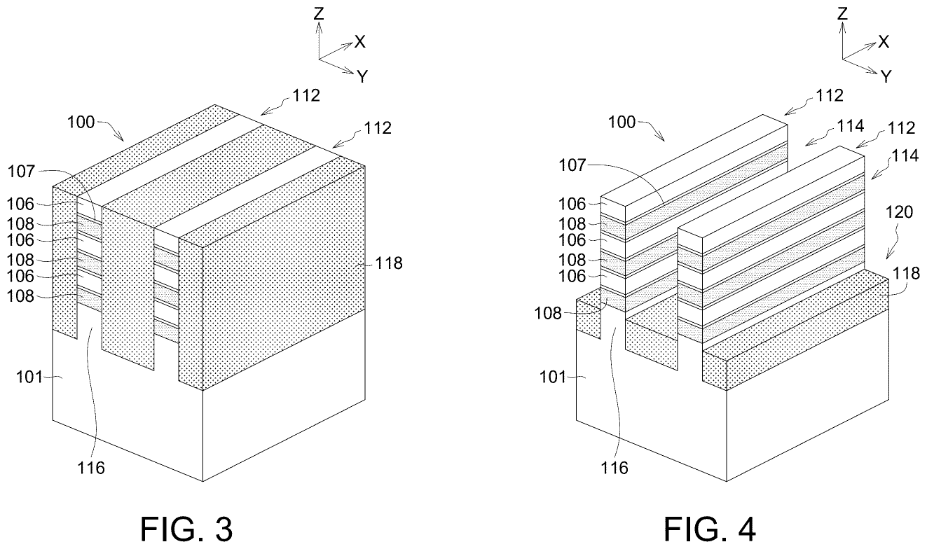

In FIG. 3, after the fin structures 112 are formed, an insulating material 118 is formed on the substrate 101. The insulating material 118 fills the trenches 114 (FIG. 2) between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or below a surface of the lowest second semiconductor layer 108 in contact with the well portion 116 formed from the substrate 101.

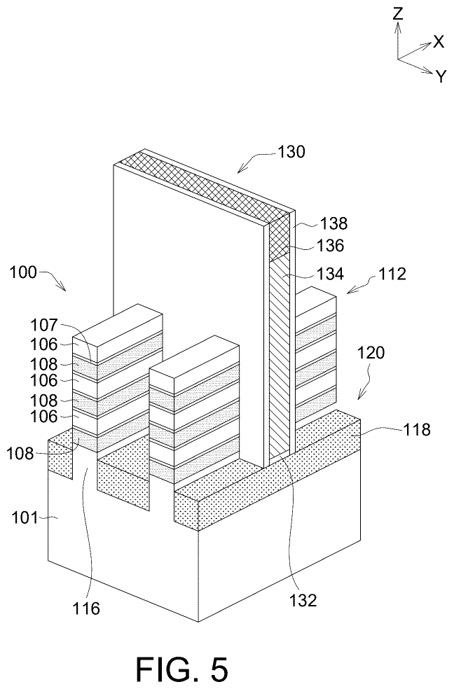

In FIG. 5, one or more sacrificial gate structures 130 are formed over the semiconductor device 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device 100. The fin structures 112 that are partially exposed on opposite sides of the sacrificial gate structure 130 define source/drain (S/D) regions for the semiconductor device 100. In some cases, some S/D regions may be shared between various transistors. For example, various one of the S/D regions may be connected together and implemented as multiple functional transistors.

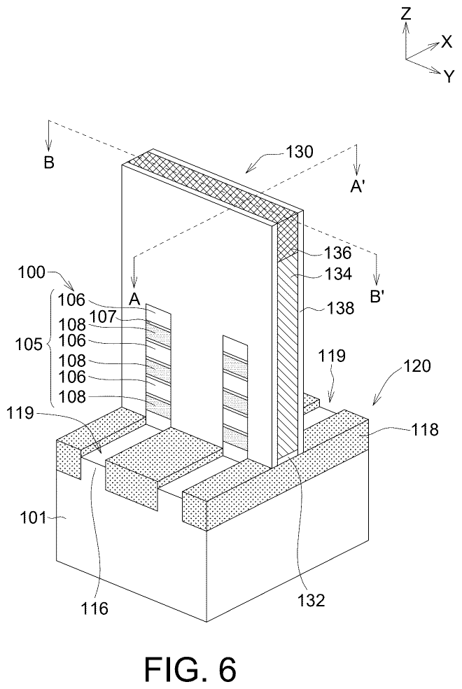

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

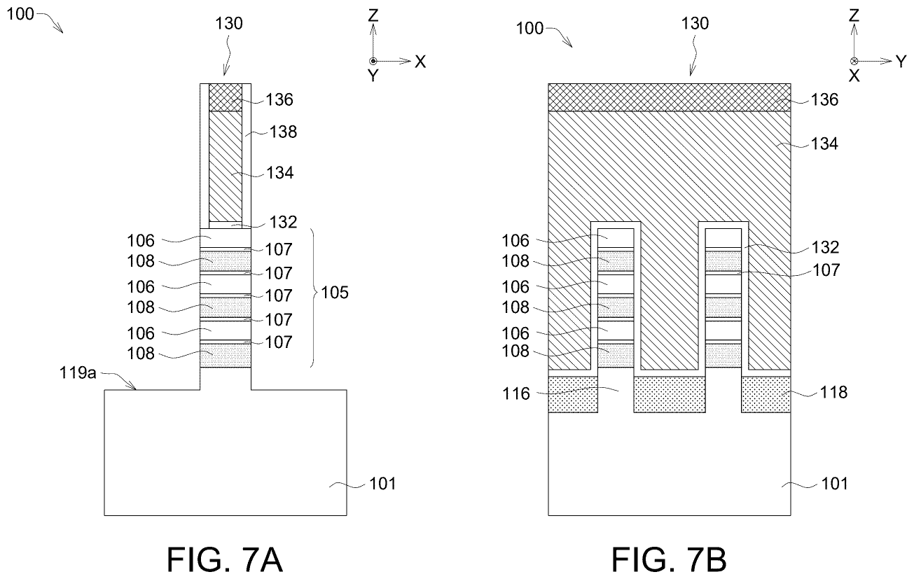

FIGS. 7A and 7B are cross-sectional views of the semiconductor device 100 taken along line A-A and line B-B of FIG. 6, respectively. Cross-section A-A is in a plane of the nanostructures 105 along the X direction. Cross-section B-B is in a plane perpendicular to cross-section A-A and is in the sacrificial gate structure 130.

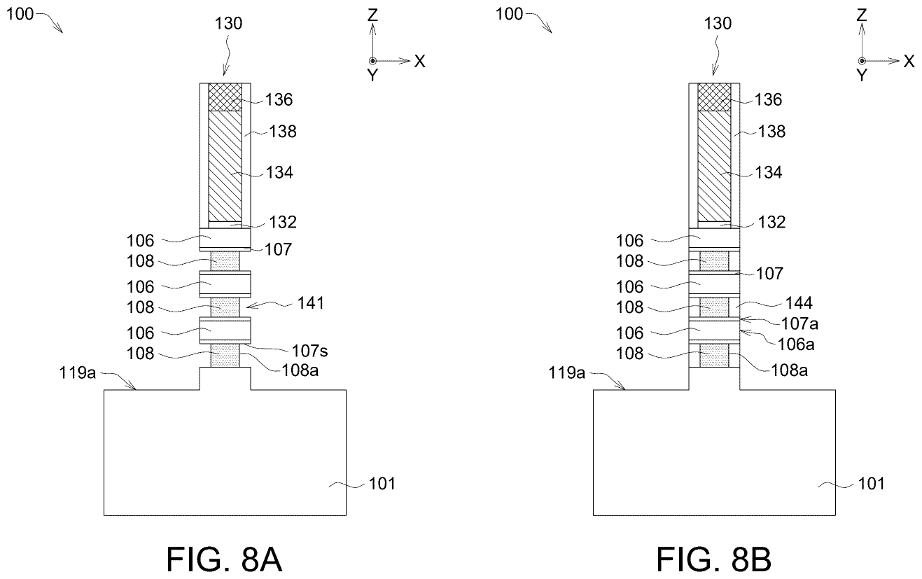

FIGS. 8A-8B are cross-sectional views of the semiconductor device 100 taken along line A-A of FIG. 6, showing various stages of manufacturing the semiconductor device 100 in accordance with some embodiments. In FIG. 8A, edge portions of each second semiconductor layer 108 of the nanostructures 105 are removed horizontally along the X direction. The removal of the edge portions of the second semiconductor layers 108 forms cavities 141. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The removal of edge portions of the second semiconductor layers 108 expose a portion of first side surfaces 107s of the diffusion barrier layers 107 along the X direction.

In FIG. 8B, after removing the edge portions of the second semiconductor layers 108, a dielectric layer is deposited in the cavities 141 (in FIG. 8A) to form dielectric spacers (or so-called inner spacers) 144. The dielectric spacers 144 may be made of a low-k dielectric material, such as SiON, SiCN, SiOC, SiOCN, or SiN. In some embodiments, the dielectric spacers 144 are formed of a material have a k value in a range of 3.5 to 5.5. The dielectric spacers 144 may be formed by atomic layer deposition (ALD), pulsed plasma CVD, or any suitable deposition process. The remaining second semiconductor layers 108 are capped between the dielectric spacers 144 along the X direction.

In FIG. 8B, end portions of the dielectric spacers 144 corresponding to each of the first semiconductor layers 106 and the diffusion barrier layers 107 may have flat surfaces which are substantially flush with the outer surfaces 106a of the first semiconductor layers 106 and the outer surfaces 107a of the diffusion barrier layers 107, as shown in FIG. 8B.

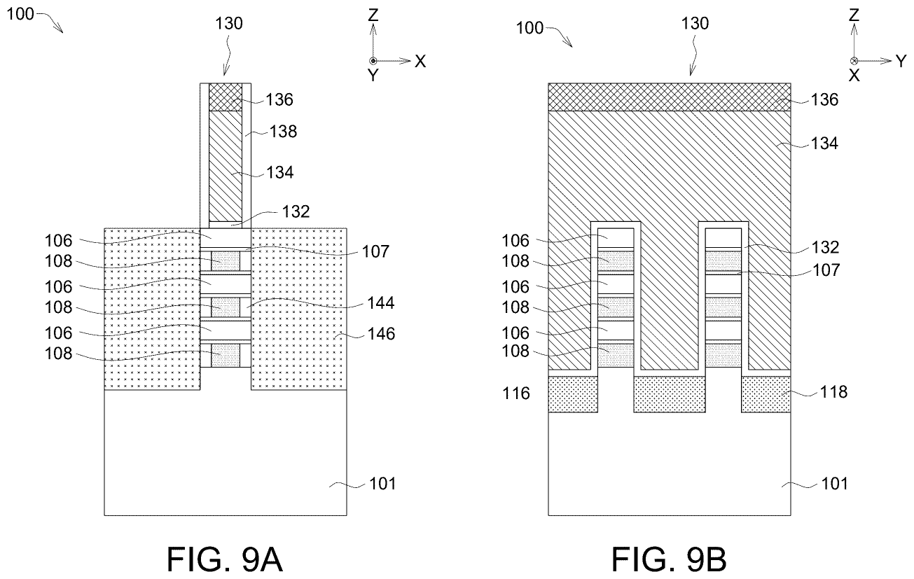

FIGS. 9A-14A are cross-sectional views of various stages of manufacturing the semiconductor device 100 taken along cross-section A-A of FIG. 6, in accordance with some embodiments. FIGS. 9B-14B are cross-sectional views of various stages of manufacturing the semiconductor device 100 taken along cross-section B-B of FIG. 6, in accordance with some embodiments. As shown in FIGS. 9A and 9B, epitaxial S/D features 146 are formed in the source/drain (S/D) regions. The epitaxial S/D features 146 may be made of one or more layers of Si, SiP, SiC and SiCP for n-channel FETs or Si, SiGe, Ge for p-channel FETs. For p-channel FETs, p-type dopants, such as boron (B), may also be included in the epitaxial S/D features 146. The epitaxial S/D features 146 may be formed by an epitaxial growth method using CVD, ALD or MBE. The epitaxial S/D features 146 may grow both vertically and horizontally to form facets, which may correspond to crystalline planes of the material used for the substrate 101. In some cases, the epitaxial S/D features 146 may grow and merge with the epitaxial S/D features 146 of the neighboring semiconductor device.

In some embodiments, prior to formation of the S/D epitaxial features 146, a S/D pre-clean process may be performed to remove a native oxide layer that is formed on the first semiconductor layers 106 and the dielectric spacers 144. The S/D pre-clean process may be an inert gas sputtering process (e.g., argon sputter) or a plasma-based cleaning process. In one embodiment, the S/D pre-clean process is a process which uses a remote plasma source to generate ammonium fluoride (NH₄F) etchant species from nitrogen trifluoride (NF₃) and ammonia (NH₃) to minimize the damage to the semiconductor device 100.

In one example shown in FIG. 9A, one of a pair of epitaxial S/D features 146 disposed on one side of the sacrificial gate structure 130 is designated as a source feature/terminal, and the other of the pair of epitaxial S/D features 146 disposed on the other side of the sacrificial gate structure 130 is designated as a drain feature/terminal. The source feature/terminal and the drain feature/terminal are connected by the channel layers (e.g., the first semiconductor layers 106). The epitaxial S/D features 146 are in contact with the first semiconductor layer 106 under the sacrificial gate structure 130. In some cases, the epitaxial S/D features 146 may grow pass the topmost semiconductor channel, i.e., the first semiconductor layer 106 under the sacrificial gate structure 130, to be in contact with the gate spacers 138. The second semiconductor layer 108 under the sacrificial gate structure 130 are separated from the epitaxial S/D features 146 by the dielectric spacers 144.

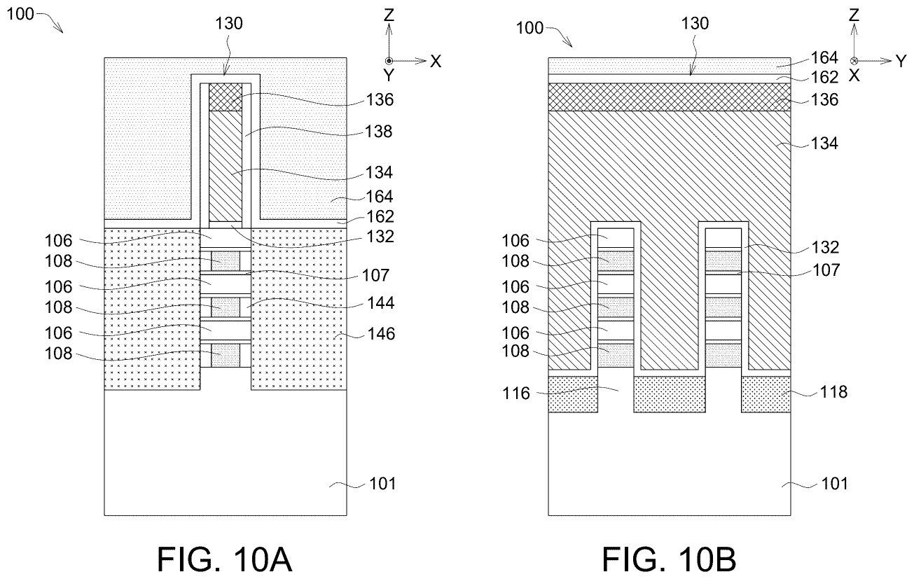

In FIGS. 10A-10B, a contact etch stop layer (CESL) 162 is conformally formed on the exposed surfaces of the semiconductor device 100. The CESL 162 covers the sidewalls of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device 100 may be subject to a thermal process to anneal the first ILD layer 164.

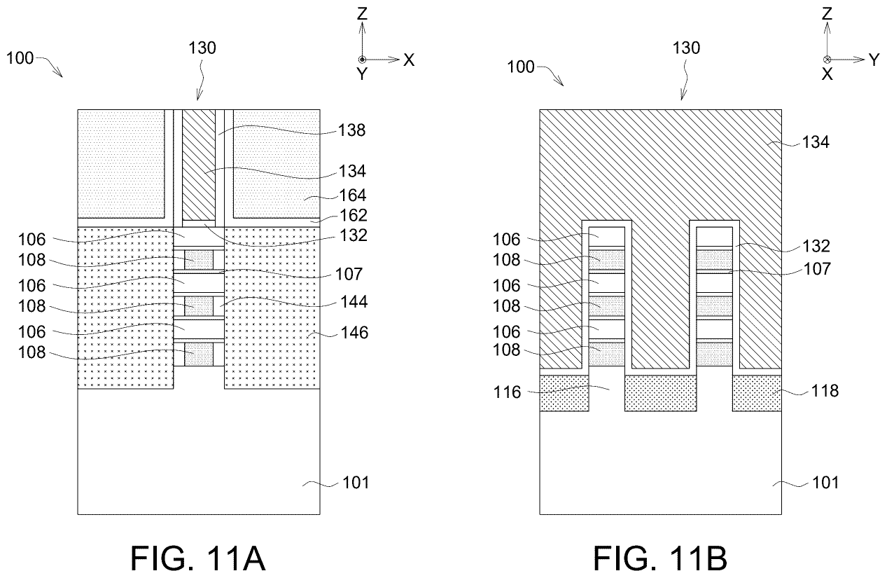

In FIGS. 11A-11B, after the first ILD layer 164 is formed, a planarization operation, such as CMP, is performed on the semiconductor device 100 until the sacrificial gate electrode layer 134 is exposed.

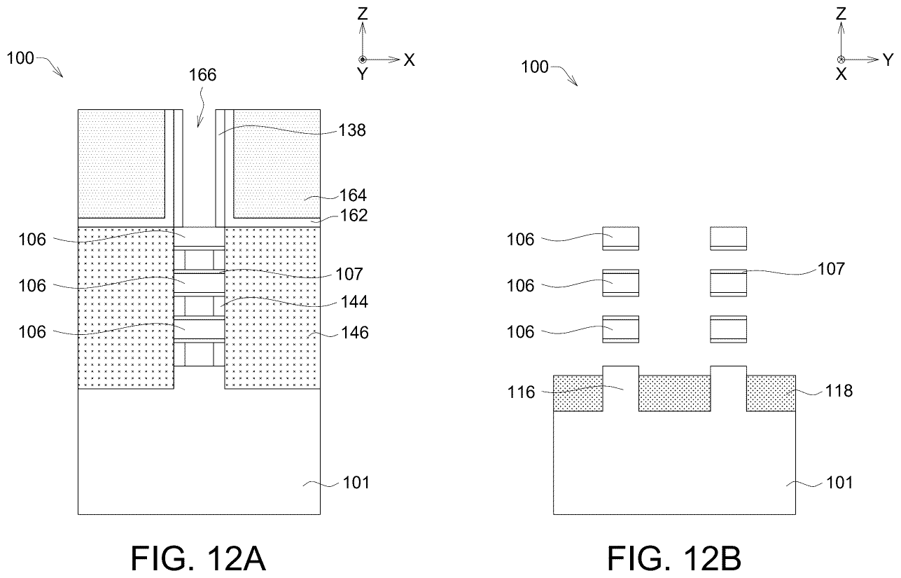

In FIGS. 12A-12B, the sacrificial gate structure 130 and the second semiconductor layers 108 are removed, while the first semiconductor layers 106, the diffusion barrier layers 107 and the dielectric spacers 144 are remained due to selective etching. In another embodiment, the sacrificial gate structure 130 and the second semiconductor layers 108 with different materials can be removed separately. The removal of the sacrificial gate structure 130 and the semiconductor layers 108 forms openings 166 between gate spacers 138 and between the diffusion barrier layers 107, respectively. The ILD layer 164 protects the S/D epitaxial features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 125, the ILD layer 164, and the CESL 162.

Portions of the second semiconductor layers 108 may be removed using a selective wet etching process. In cases where the diffusion barrier layers 107 are made of SiGeC, the second semiconductor layers 108 are made of SiGe and the first semiconductor layers 106 are made of Si, the chemistry used in the selective wet etching process removes the SiGe while not substantially affecting Si and SiGeC, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

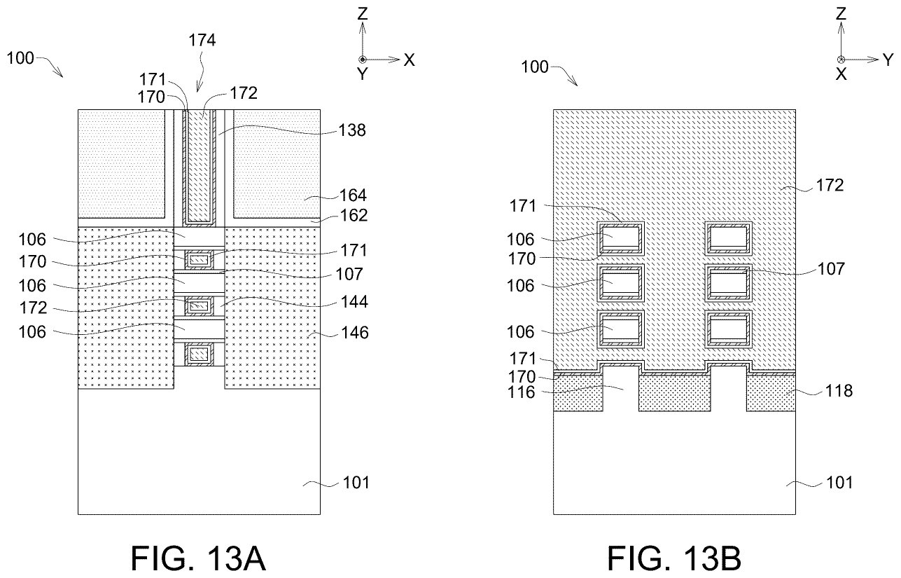

In FIGS. 13A-13B, after the formation of the nanostructure channels (i.e., the exposed first semiconductor layers 106 and diffusion barrier layers 107), a gate dielectric layer 171 is formed to surround the first semiconductor layers 106 and diffusion barrier layers 107, and a gate electrode layer 172 is formed on the gate dielectric layer 171. The gate dielectric layer 171 and the gate electrode layer 172 may be collectively referred to as a gate structure 174. In some embodiments, an interfacial layer (IL) 170 is formed between the gate dielectric layer 171 and the exposed surfaces of the first semiconductor layers 106 and the diffusion barrier layers 107. In such cases, the IL 170 may also form on the well portion 116 of the substrate 101. The IL 170 may include or be made of an oxygen-containing material or a silicon-containing material, such as silicon oxide, silicon oxynitride, oxynitride, hafnium silicate, etc. The IL 170 may be formed by CVD, ALD, a clean process, or any suitable process. In some embodiments, the gate dielectric layer 171 includes one or more layers of a dielectric material, such as silicon oxide, silicon nitride, or high-K dielectric material, other suitable dielectric material, and/or combinations thereof. Examples of high-k dielectric material include HfO₂, HfSiO, HfSiON, HfTaO, HfSiO, HfZrO, zirconium oxide, aluminum oxide, titanium oxide, hafnium dioxide-alumina (HfO₂-Al₂O₃) alloy, other suitable high-k dielectric materials, and/or combinations thereof. The gate dielectric layer 171 may be formed by CVD, ALD or any suitable deposition technique.

In some embodiments, the diffusion barrier layers 107 may be located on two opposing surfaces of the first semiconductor layers 106 except the uppermost first semiconductor layer 106. That is, no diffusion barrier layer 107 is located on the top surface of the uppermost semiconductor layer 106. The diffusion barrier layers 107 may have a thickness in a range between about 0.2 nm and about 5 nm. The first semiconductor layers 106 may have a thickness in a range between about 2 nm and 10 nm. In some embodiments, the diffusion barrier layers 107 is made of SiGeC having a carbon concentration in a range between about 0.1% and 10%. For example, the carbon concentration of the diffusion barrier layers 107 may be between about 10²⁰ atoms/cm³ and 10²² atoms/cm³.

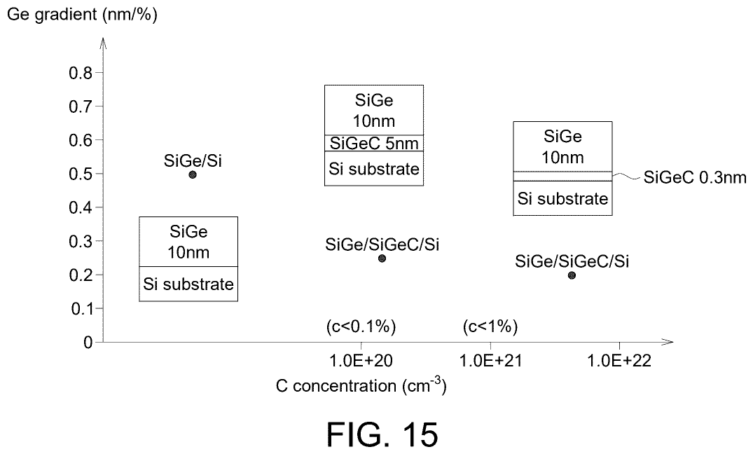

The X-ray diffractometer (XRD) measurements also confirm the efficiency of using the diffusion barrier layers 107 to retard Ge diffusion by occupying vacancies or interstitial sites in SiGe semiconductor layer. Referring to FIG. 15, FIG. 15 illustrates a comparison of germanium gradient and carbon concentration in three nanostructures containing SiGe/Si, SiGe/SiGeC/Si and SiGe/SiGeC/Si. For example, Ge gradient of SiGe/Si intermix is higher than the Ge gradient of SiGeC layer between the SiGe layer and Si layer, while carbon concentration of SiGeC layer between the SiGe layer and Si layer is higher than the carbon concentration of SiGe/Si intermix. The carbon concentration of SiGe/Si intermix is almost zero.

As shown in FIG. 15, when the carbon concentration of SiGeC layer between the SiGe layer and Si layer is increased, such as increased from 0% to 2%, the Ge gradient of SiGeC layer is decreased from 0.5 nm/% to 0.2 nm/%. This is proved that carbon atoms can retard Ge diffusion to Si layer by occupying vacancies or interstitial sites in SiGe layer.

The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the first ILD layer 164. The gate dielectric layer 170 and the gate electrode layer 172 formed over the first ILD layer 164 are then removed by using, for example, CMP, until the top surface of the first ILD layer 164 is exposed.

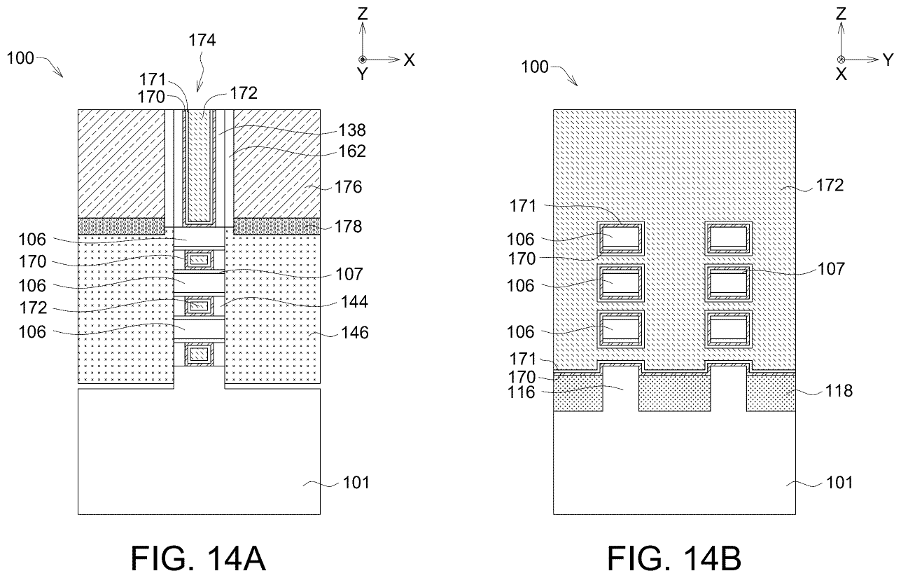

In FIGS. 14a-14b, source/drain (s/d) contacts 176 are formed in the first ILD layer 164. Prior to forming the S/D contacts 176, contact openings are formed in the first ILD layer 164 to expose the epitaxial S/D features 146. Suitable photolithographic and etching techniques are used to form the contact openings through various layers, including the first ILD layer 164 and the CESL 162 to expose the epitaxial S/D features 146. In some embodiments, the upper portions of the epitaxial S/D features 146 are etched.

After the formation of the contact openings, a silicide layer 178 is formed on the epitaxial S/D features 146. The silicide layer 178 conductively couples the epitaxial S/D features 146 to the subsequently formed S/D contacts 176. The silicide layer 178 may be formed by depositing a metal source layer over the epitaxial S/D features 146 and performing a rapid thermal annealing process. During the rapid annealing process, the portion of the metal source layer over the epitaxial S/D features 146 reacts with silicon in the epitaxial S/D features 146 to form the silicide layer 178. Unreacted portion of the metal source layer is then removed. In some embodiments, the silicide layer 178 is made of a metal or metal alloy silicide, and the metal includes a noble metal, a refractory metal, a rare earth metal, alloys thereof, or combinations thereof. Next, a conductive material is formed in the contact openings and form the S/D contacts 176. The conductive material may be made of a material including one or more of Ru, Mo, Co, Ni. W, Ti, Ta, Cu, Al, TiN and TaN. While not shown, a barrier layer (e.g., TiN, TaN, or the like) may be formed on sidewalls of the contact openings prior to forming the S/D contacts 176. Then, a planarization process, such as CMP, is performed to remove excess deposition of the contact material and expose the top surface of the gate electrode layer 172.

It is understood that the semiconductor device 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

The present disclosure relates to a semiconductor device and a manufacturing method thereof, in which less SiGe intermix and better Si-nanosheet surface roughness for sheet height scaling by the insertion of SiGeC layer can be achieved. Since the dummy SiGe layer removal for Si-nanosheet formation results in serious surface roughness to degrade the carrier mobility and influence the capability for further sheet height scaling, it is optimized for the SiGe etching and removal recipe by insertion of SiGeC to reduce the SiGe intermix and improve the surface roughness.

According to some embodiments of the present disclosure, a method of manufacturing a semiconductor device is provided. A stack of nanostructures having a plurality of first semiconductor layers, a plurality of diffusion barrier layers and a plurality of second semiconductor layers alternately stacked is formed, wherein each of the diffusion barrier layers is disposed between the first and second semiconductor layers. Edge portions of the second semiconductor layers is removed to form a plurality of cavities between the diffusion barrier layers. A dielectric spacer is formed on sidewalls of the second semiconductor layers and fills the cavities. An epitaxial source/drain feature is formed such that a side surface of the epitaxial source/drain feature contacts the first semiconductor layers, the diffusion barrier layers and the dielectric spacers.

According to some embodiments of the present disclosure, a method of manufacturing a semiconductor device is provided. A stack of nanostructures are formed on a substrate, the nanostructures comprises a plurality of first semiconductor layers, a plurality of diffusion barrier layers and a plurality of second semiconductor layers that are alternately stacked, wherein each of the diffusion barrier layers is disposed between the first and second semiconductor layers. A sacrificial gate structure is formed over a portion of the nanostructures. The first semiconductor layers, the diffusion barrier layers and the second semiconductor layers not covered by the sacrificial gate structure in a source/drain region of the nanostructures are removed. The edge portions of the second semiconductor layers are removed. A plurality of dielectric spacers is formed on sidewalls of the second semiconductor layers and between the diffusion barrier layers. An epitaxial source/drain feature is formed in the source/drain region. The sacrificial gate structure is removed to expose the first semiconductor layers and the diffusion barrier layers. The second semiconductor layers is removed to form a plurality of cavities between the diffusion barrier layers. A gate dielectric layer is formed into the cavities to surround exposed surfaces of each of the first semiconductor layers and the diffusion barrier layers. A gate electrode layer is formed on the gate dielectric layer.

According to some embodiments of the present disclosure, a semiconductor device including a substrate, a first source/drain epitaxial feature, a second source/drain epitaxial feature, two or more semiconductor layers, and a plurality of diffusion barrier layers is provided. The first source/drain epitaxial feature is disposed in a first source/drain region. The second source/drain epitaxial feature disposed in a second source/drain region. The semiconductor layers and the diffusion barrier layers are disposed between the first source/drain epitaxial feature and the second source/drain epitaxial feature, and the diffusion barrier layers are disposed between two adjacent semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a stack of nanostructures having a plurality of first semiconductor layers, a plurality of diffusion barrier layers and a plurality of second semiconductor layers alternately stacked, wherein each of the diffusion barrier layers is disposed between the first and second semiconductor layers;
removing portions of the second semiconductor layers to form a plurality of cavities between the diffusion barrier layers;
forming a dielectric spacer on sidewalls of the second semiconductor layers to fill the cavities;
forming an epitaxial source/drain feature such that a side surface of the epitaxial source/drain feature contacts the first semiconductor layers, the diffusion barrier layers and the dielectric spacers; and
removing the second semiconductor layers to form a plurality of openings between the diffusion barrier layers.

2. The method of claim 1, wherein the diffusion barrier layers are made of semiconductor materials having carbon (C), tellurium (Te), antimony (Sb), tin (Sn) or a combination thereof.

3. The method of claim 1, wherein the diffusion barrier layers are made of SiGeM having a M concentration range between 0.1% and 10%, wherein M is at least one element selected from a group of carbon (C), tellurium (Te), antimony (Sb) and tin (Sn).

4. The method of claim 1, wherein each of the diffusion barrier layers has a thickness in a range between 0.3 nm and 5 nm.

5. The method of claim 1, wherein the diffusion barrier layers are formed by a chemical vapor deposition process or an atomic layer deposition process.

6. The method of claim 1, wherein the diffusion barrier layers are formed by depositing an element on surfaces of the first and second semiconductor layers to reduce SiGe intermix between the first and second semiconductor layers.

7. The method of claim 1, wherein a surface roughness of the first semiconductor layers is in a range between 0.13 nm and 0.16 nm after removing the second semiconductor layers.

8. A method of manufacturing a semiconductor device, comprising:
forming a stack of nanostructures on a substrate, the nanostructures comprising a plurality of first semiconductor layers, a plurality of diffusion barrier layers and a plurality of second semiconductor layers that are alternately stacked, wherein each of the diffusion barrier layers is disposed between the first and second semiconductor layers;
forming a sacrificial gate structure over a portion of the nanostructures;
removing the first semiconductor layers, the diffusion barrier layers and the second semiconductor layers exposed through the sacrificial gate structure in a source/drain region of the nanostructures;
forming an epitaxial source/drain feature in the source/drain region;
removing the sacrificial gate structure to expose the first semiconductor layers, the diffusion barrier layers and the second semiconductor layers;
removing the second semiconductor layers to form a plurality of openings between the diffusion barrier layers;
forming a gate dielectric layer into the openings to surround exposed surfaces of each of the first semiconductor layers and the diffusion barrier layers; and
forming a gate electrode layer on the gate dielectric layer.

9. The method of claim 8, wherein the diffusion barrier layers are made of semiconductor materials having carbon (C), tellurium (Te), antimony (Sb), tin (Sn) or a combination thereof.

10. The method of claim 8, wherein the diffusion barrier layers are made of SiGeM having a M concentration range between 0.1% and 10%, wherein M is at least one element selected from a group of carbon (C), tellurium (Te), antimony (Sb) and tin (Sn).

11. The method of claim 8, wherein each of the diffusion barrier layers has a thickness in a range between 0.3 nm and 5 nm.

12. The method of claim 8, wherein the diffusion barrier layers are formed by a chemical vapor deposition process or an atomic layer deposition process.

13. The method of claim 8, wherein the diffusion barrier layers are formed by depositing an element on surfaces of the first and second semiconductor layers to reduce SiGe intermix between the first and second semiconductor layers.

14. The method of claim 8, wherein before forming the epitaxial source/drain feature in the source/drain region, the method further comprises:
removing edge portions of the second semiconductor layers; and
forming a plurality of dielectric spacers on sidewalls of the second semiconductor layers and between the diffusion barrier layers.

15. A semiconductor device, comprising:
a substrate;
a first source/drain epitaxial feature disposed in a first source/drain region;
a second source/drain epitaxial feature disposed in a second source/drain region;
two or more semiconductor layers disposed between the first source/drain epitaxial feature and the second source/drain epitaxial feature; and
a plurality of diffusion barrier layers disposed between the two or more semiconductor layers adjacent to each other.

16. The semiconductor device of claim 15, wherein the diffusion barrier layers are made of semiconductor materials having carbon (C), tellurium (Te), antimony (Sb), tin (Sn) or a combination thereof.

17. The semiconductor device of claim 15, wherein the diffusion barrier layers are made of SiGeM having a M concentration range between 0.1% and 10%, wherein M is at least one element selected from a group of carbon (C), tellurium (Te), antimony (Sb) and tin (Sn).

18. The semiconductor device of claim 15, wherein each of the diffusion barrier layers has a thickness in a range between 0.3 nm and 5 nm.

19. The semiconductor device of claim 15, wherein each of the diffusion barrier layers has an element deposited on surfaces of the semiconductor layers to reduce SiGe intermix in the semiconductor layers.

20. The semiconductor device of claim 15, wherein a surface roughness of the semiconductor layers is in a range between 0.13 nm and 0.16 nm with the insertion of the diffusion barrier layers.
